(19) United States
(12) Patent Application Publication
(10) Pub. No.: US 2026/0173431 A1
(43) Pub. Date: Jun. 18, 2026

(54) COMPLIANT BUFFER LAYERS FOR GAN-BASED DEVICES

(71) Applicant: Analog Devices, Inc., Wilmington, MA (US)

(72) Inventor: Mohamed Azize, Medford, MA (US)

(21) Appl. No.: 19/423,556

(22) Filed: Dec. 17, 2025

Related U.S. Application Data
(60) Provisional application No. 63/735,302, filed on Dec. 17, 2024.

(51) Int. Cl. H10D 30/47; H10D 30/01; H10D 62/10; H10D 62/815; H10D 64/00

(52) U.S. Cl. CPC H10D 30/475; H10D 30/015; H10D 62/102; H10D 62/8164; H10D 64/112; H10D 64/117

(57) ABSTRACT

Methods of forming compound semiconductors devices, such as GaN-based high electron mobility transistors (HEMTs) are described. AlScN can be employed for lattice-matching to a GaN layer. A “two-dimensional” (2D) (e.g., graphene, MoS2, HbN, Si, or other) intermediate layer can act as a sacrificial layer, or can be selectively removed such as to leave behind a back-side electric field plate for the GaN HEMT device. Back-barrier layer and “superlattice” formation techniques are described, along with backside processing and layer formation and phase-change compliant layers. Certain steps can involve concurrent chemical vapor deposition (CVD) and physical vapor deposition (PVD), e.g., sputtering, at lower temperature than otherwise possible using Metal organic chemical vapor deposition (MOCVD).

### CLAIM OF PRIORITY

This application claims the benefit of priority of U.S. Provisional Patent Application Number 63/735,302 entitled COMPLIANT BUFFER LAYERS FOR GAN-BASED DEVICES, filed on Dec. 17, 2024 (Attorney Docket No. 3967.C94PRV), which hereby is incorporated by reference herein in its entirety.

### TECHNICAL FIELD

This document pertains generally, but not by way of limitation, to semiconductor devices and manufacturing, and more particularly, but not by way of limitation to compliant buffer layers for forming GaN heterostructure structures and other AlₓGa₁₋ₓN-based devices.

### BACKGROUND

Compound semiconductors can provide advantages over silicon in forming integrated circuit devices. Some compound semiconductors allow for optical or photonic applications, and some compound semiconductors provide wide bandgaps that can be useful in high-voltage or high-power applications, such as for power transistors and radio-frequency (RF) communication applications. However, processing compound semiconductors can be more expensive and more complicated than processing silicon.

### SUMMARY/OVERVIEW

One problem in compound semiconductor devices can arise from a desire to reduce expense by forming the compound semiconductor on a less expensive substrate, such as a silicon substrate. For example, gallium nitride (GaN) is a useful compound semiconductor, which can be grown or otherwise formed upon a less expensive silicon substrate, but a lattice and thermal mismatch between the GaN the silicon can cause defects in the GaN that can degrade device operation of field-effect transistors (FETs) or other GaN devices. The FETs can employ bilayer or other heterostructures, such as a GaN layer upon which an aluminum gallium nitride (AlGaN) layer can be formed, such as to create a two-dimensional electron gas (“2DEG”) conductive layer region located between two insulating layers. While the resulting structure can be a depletion-mode (normally on) FET, it is also possible and desirable to provide a resulting structure that be an enhancement mode (EMODE, normally off) FET device.

For example, a portion of the region between the source and drain terminals of the FET can be selectively etched to remove the 2DEG gas over that selectively-etched portion, and when it is desired that the FET be turned on, the FET gate terminal can be biased positively to inject electrons from the FET gate region to form the 2DEG gas in that selectively-etched portion.

Another approach is to selectively form a p-type GaN gate region under the gate terminal to create a PN junction with the underlying AlGaN material, such as to form a depletion region under the selectively-formed p-type GaN gate region, which will be depleted of electrons and be normally off, thereby providing an enhancement mode FET device. By biasing the gate terminal positively, an electron channel region can be created using the selectively-formed p-type GaN gate region, such that a continuous channel can be formed between the source and drain of the GaN FET device to provide an enhancement mode “on” state of the FET. Providing the p-type GaN region for forming an enhancement mode device, however, will impact the drain-to-source sheet resistance. Because the channel region may not provide enough electrons to form a 2DEG electron gas, the higher channel region “on”-resistance (Ron) may impede the efficiency of the FET device, such as in a power transistor application.

This Summary/Overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

FIG. 1 shows a side cross-sectional view of an example of a semiconductor structure of a lateral GaN high electron mobility transistor (HEMT).

FIG. 2 shows a side cross-sectional view of an example of a semiconductor structure in an approach in which GaN epitaxy employing crystal growth by MOCVD can be carried out on a silicon wafer substrate.

FIG. 3 shows a side cross-sectional view of a semiconductor structure according to an example of the present approach, which can employ one or both of at least two techniques that are described.

FIG. 4A is a cross-sectional representation that shows an example of further semiconductor processing manufacturing in which a sacrificial layer can be formed on an AlN or AlₓSc₁₋ₓN layer.

FIG. 4B shows a cross-sectional diagram of a resulting enhancement mode (E-MODE) HEMT.

FIG. 4C shows a cross-sectional diagram of a resulting depletion mode (D-MODE) HEMT.

FIG. 4D shows a cross-sectional diagram of a portion of a monolithic IC that can include both D-MODE HEMTs and E-MODE HEMTs.

FIGS. 5A, 5B, 5C, and 5D are cross-sectional diagrams showing an example in which the sacrificial layer need not be removed, and can be used form back-side field plates for HEMTs.

FIG. 6 illustrates a cross-sectional diagram of an illustrative example of an enhancement mode HEMT, along with an illustrative example of suitable dimensions of certain regions of the illustrated HEMT.

FIGS. 7A, 7B, 7C, and 7D are cross-sectional diagrams that illustrate an example in which the graphene or other sacrificial layer can be selectively patterned.

FIG. 8A is a cross-sectional diagram that illustrates an example in which the back-side field plate can be provided using a 2DEG electron gas.

FIGS. 8B, 8C, and 8D are cross-sectional diagrams that show illustrative examples of cross-sections of resulting depletion mode (FIG. 8C) and enhancement mode (FIG. 8B) HEMT structures, such as can be formed in accordance with the techniques explained with respect to FIG. 8A.

FIG. 9 illustrates a cross-sectional diagram of an illustrative example of a corresponding enhancement mode HEMT, such as can be made as described with respect to FIGS. 8A-8D, having a buried 2DEG electron gas back-field plate.

FIGS. 10A, 10B, 10C, and 10D include cross-sectional diagrams of an illustrative example of an approach that can employ a “superlattice” such as for lattice-matching with an overlying GaN layer.

FIG. 11 shows a graph of lattice constant parameter, a, in Angstroms, VS. percentage of Scandium (Sc) composition for various compositions of AlₓSc₁₋ₓN.

FIGS. 12A, 12B, and 12C include cross-sectional diagrams that illustrate an example of the present approach of employing low temperature CVD with concurrent PVD to form the AlₓSc₁₋ₓN layer on the backside of the (e.g., thinned) Si or other substrate.

FIG. 13 includes a cross-sectional diagram that shows an example of an approach that can provide a low cost SiC buffer for high crystalline quality GaN grown thereupon.

FIGS. 14A, 14B, 14C, and 14D include cross-sectional diagrams that show an example in which a high crystalline Al—AlScN/diamond buffer can be provided, such as for manufacturing AlGaN/GaN HEMTs.

FIG. 15 is a cross-sectional diagram showing an example in which an Al, Ga, Ga:In, In, or other like film can be used as a phase-changing compliant layer. FIGS. 16A, 16B, 16C, and 16D illustrate an example of how the techniques described herein, such as with respect to FIG. 15, including its phase-change-to-liquid compliant layer can be further processed, such as to leave behind selectively patterned back-side field plates or other structures.

### DETAILED DESCRIPTION

This document describes, among other things, nucleation and buffer layer technologies, such as which can be employed on silicon or other substrates being used for forming a compound semiconductor such as a gallium nitride (GaN) based semiconductor thereupon, such as for making GaN high electron mobility transistor (HEMT) devices, such as for high voltage or high power or radio frequency (RF) or other high frequency communications.

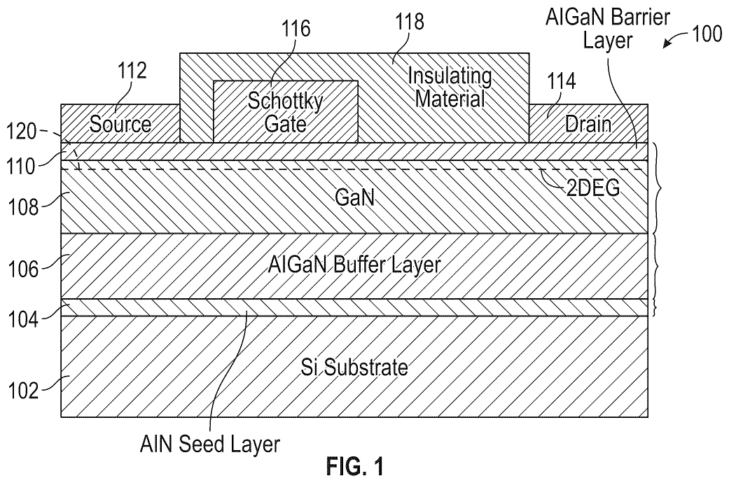

FIG. 1 shows an example of a structure of a depletion mode lateral GaN HEMT 100, such as which can be used in power or radiofrequency (RF) or other wireless applications. In this example, a semiconductor substrate, such as an inexpensive silicon (Si) substrate 102 can be used, such as which can allow co-integration with complementary “metal” “oxide” (“CMOS”) semiconductor devices. Upon the Si substrate 102, an aluminum nitride (AlN) seed layer 104 can be formed, such as by using low temperature epitaxy. On the AlN seed layer 104, an AlGaN buffer layer 106 can be formed, such as by using low temperature epitaxy. On the AlGaN buffer layer 106, a compound semiconductor layer, such as a GaN compound semiconductor layer 108 can be formed, such as by using high temperature epitaxy. On the GaN compound semiconductor layer, 108 an AlGaN barrier layer 110 can be formed, such as using high temperature epitaxy. On the AlGaN barrier layer 110, a source region 112, a drain region 114, and a Schottky gate region 116 can be formed. An insulating material 118 can be placed between the gate 116 and source 112 and between the gate 116 and drain 114, and over the gate 116. The AlGaN barrier layer 110 and the GaN layer 108 form a bi-layer, such that the GaN layer 108 provides a HEMT body region in which a 2DEG electron gas 120 can be formed. Metal organic chemical vapor deposition (MOCVD) and molecular beam epitaxy (MBE) can be used to perform the both the low temperature (LT) epitaxy and the high temperature (HT) epitaxy processing used to manufacture the device shown in FIG. 1.

GaN epitaxy can be extremely challenging, such as due to the lattice and thermal mismatches between the layers involved. These can induce a large total tensile stress during the high temperature epitaxy in the MOCVD chamber, e.g., at 1000 degrees Celsius, and during the cooling down step from 1000 degrees Celsius to room temperature. The thicker the GaN layer 108, the more defects will be present in the GaN layer 108 (e.g., cracks and dislocations). To address this problem, GaN epitaxy can be used. The GaN epitaxy can employ nucleation (e.g., AlN layer 104) and buffer layer techniques (e.g., one or more low temperature AlN/GaN buffer layers 106, which can include one or more graded AlGaN layers such as with varying Al content, and/or AlN/GaN super lattices). To help avoid or reduce defects and dislocations in a thick GaN layer 108, such buffer layer techniques can be employed such as to generate compressive stress and filter out threading defects (e.g., dislocation). Certain approaches to GaN nucleation, such as using AlN layer 104 may be limited to a AlN layer 104 that is less than or equal to 200 nanometers thickness. This can be because of the low growth rate of the AlN layer 104 and roughness, delamination, or deterioration of the quality of the AlN layer 104. Moreover, due to high temperature MOCVD processes, the interface between the AlN nucleation layer 104 and the underlying Si substrate 102 can become contaminated and electrically conductive. This can be undesirable, such as for high voltage, high power, and/or RF applications. The epitaxy buffer layers schemes, such as which can include AlGaN buffer layer 106, can be relatively different and complex to establish a buffer technology platform for 12-1700 V for GaN power devices. Therefore, the reliability issues can be different for the different types of buffer layer techniques (e.g., thin vs. thick buffer layers).

Moreover, the buffer layer epitaxy for 1200 Volt and above high-voltage and high-power applications can be extremely difficult to obtain using high temperature MOCVD to form the buffer layers, resulting in poor yield, larger wafer diameter, and therefore more stress engineering.

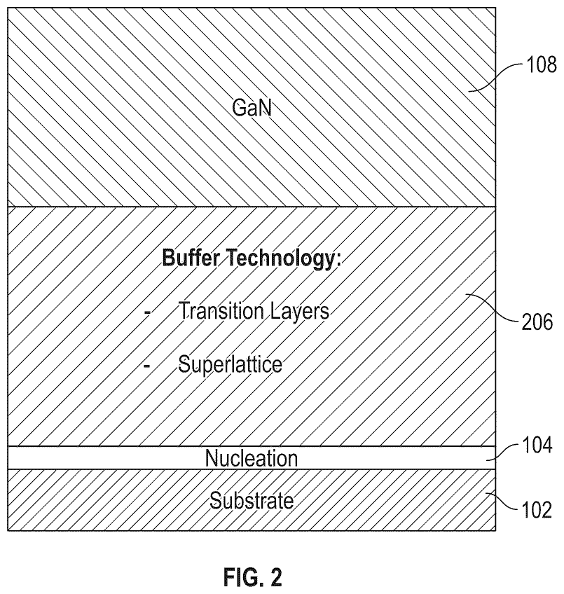

FIG. 2 shows an example of a comparative approach, such as in which GaN epitaxy employing crystal growth by MOCVD can be carried out on a silicon wafer substrate 102. A thin buffer layer 206, between the silicon substrate 102 and the GaN 108, can be less than or equal to 2 microns in thickness, such as for voltage applications that are less than or equal to 200V. One or both of low temperature or high temperature MOCVD can be employed, such as to form a stack of one or more AlN/GaN bilayer(s) in the buffer layer 106 structure. For example, an individual bilayer can include layer pairs, such as with corresponding thicknesses of 50-200 nanometers for the AlN layer(s) and a thickness of 200-2000 nanometers for the corresponding GaN layer in an individual one of the bi-layers in the buffer layer 106. For higher voltage applications (e.g., greater than 200 Volts) a thicker buffer layer 206 of greater than or equal to 2 microns in thickness can be employed. This thicker buffer layer 206 can include a stack of AlₓGa₁₋ₓN transition layers (x˜80% to 10%, ≤5 microns) , such as in which the aluminum content can be graded so as to be decreased in aluminum concentration in a direction moving away from the underlying Si substrate 102 and toward the overlying GaN layer 108. As an alternative to such a stack of AlₓGa₁₋ₓN transition layers in the buffer layer 206, an AlN/GaN superlattice can be employed in the buffer layer 206. Such a superlattice in the buffer layer 206 can include a nanostructured material that can be created by alternating very thin layers of aluminum nitride (AlN) and gallium nitride (GaN), thereby forming a repeating pattern of these two semiconductor materials, which can be used to manipulate electronic properties due to the quantum confinement effects within these extremely thin layers. For example, each of the AlN and GaN layers in the stack included in the buffer layer 206 can be between 0.5 nanometers to 1.0 nanometers thick, with these bi-layers of AlN and GaN being stacked to provide a total thickness of less than or equal to about 5 microns.

FIG. 3 shows an Example 1 of the present approach, which can employ one or both of at least two techniques that are described. First, a low temperature AlN nucleation layer 104 can be formed on the Si substrate 102. This can be performed at a temperature of less than 400 degrees Celsius, such as by using a chemical vapor deposition (CVD) with physical vapor deposition (PVD) process. Such a process can involve orienting the semiconductor wafers being processed vertically within a chamber, such as to allow a PVD process such as sputtering to occur. This CVD with concurrent PVD approach can allow creating a thick AlN nucleation layer 104 and a clean AlN/Si interface, unlike AlN deposited by high temperature MOCVD on a Si wafer, such as at a temperature of around 1000 degrees Celsius. In Example 1 of the present approach, the lower temperature CVD with concurrent PVD approach can be employed to create a tri-layer structure that can include a lattice-matched AlₓSc₁₋ₓN/Sacrificial layer/AlₓSc₁₋ₓN. This tri-layer structure can be repeated in further vertical stacking of multiple such tri-layers in a buffer layer 306, such as to help filter dislocations and to generate compressive stress before then growing the GaN layer 108 such as by MOCVD.

In this Example 1 of the present approach using low temperature (<400 degrees C) CVD with concurrent PVD, there is no need to have very thick buffer layer 306 for 1200 V and above voltage applications. Instead, the buffer layer 306 can have a thickness of less than or equal to 6 microns because of the high nucleation vertical breakdown voltage that can be obtained using this Example 1 of the present approach. For a low voltage application, a thin (e.g., 50 nanometer thick) AlN layer 104 can be formed, such as which can provide a breakdown voltage rating of between 50 Volts and 75 Volts, based on the AlN theoretical electric field breakdown. For a medium voltage application, a medium thickness (e.g., 250 nanometer thick) AlN layer 104 can be formed, such as which can provide a breakdown voltage rating of between 250 Volts and 375 Volts. For a high voltage application, a thick (e.g., 1.5 micron thickness) AlN layer 104 can be formed, such as which can provide a breakdown voltage rating of between 1.5 kV and 1.7 kV.

Optionally, the AlN layer 104 can instead be an AlₓSc₁₋ₓN layer 104, e.g., such as with a thickness between 1 nanometer and 2000 nanometers. Not only can the AlₓSc₁₋ₓN material in layer 104 be lattice matched to GaN material (thereby resulting in less dislocations to help improve GaN crystal quality), it can also act as a large energy back barrier and/or back field plate. This can help avoid electron trapping into layers underneath the AlₓSc₁₋ₓN layer 104, which can help provide better reliability.

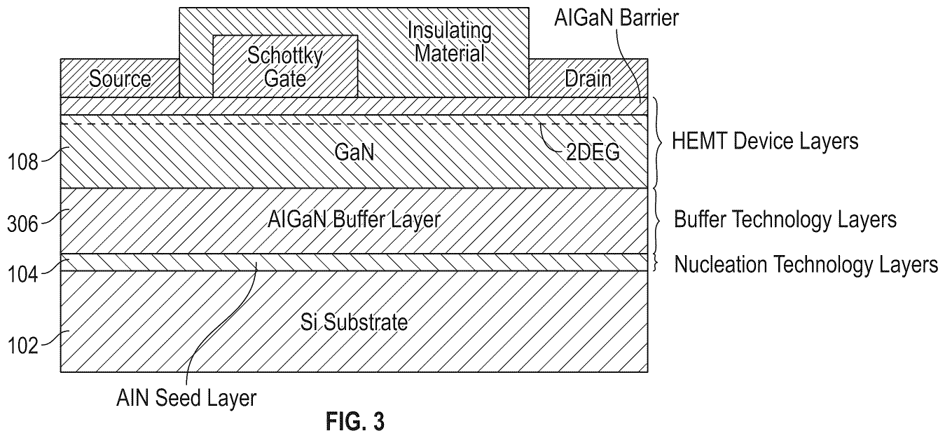

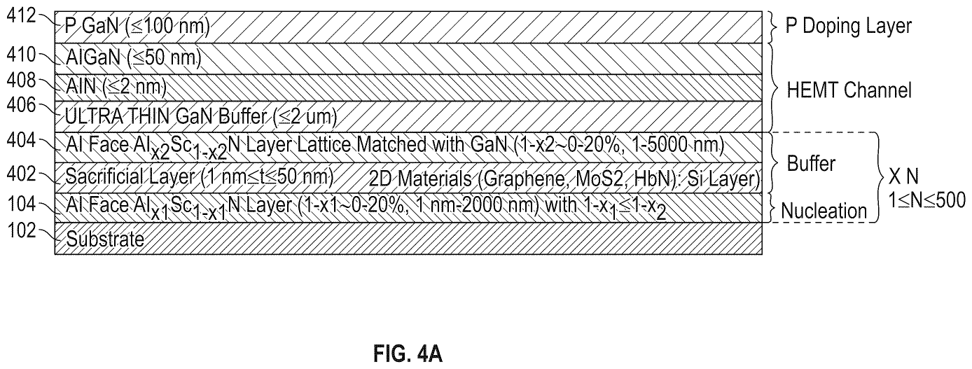

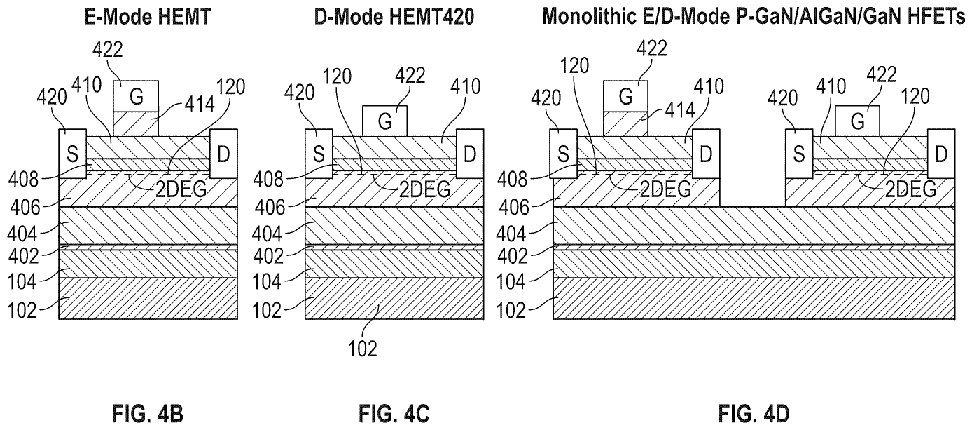

FIG. 4A is a cross-sectional representation that shows an example of further semiconductor processing manufacturing in which a sacrificial layer 402 can be formed on the AlN or AlₓSc₁₋ₓN layer 104, e.g., such as having a thickness in a range of 1 nanometer and 50 nanometers. For example, the sacrificial layer 402 can include a 2D material (e.g., graphene, HbN, MoS₂, or the like), or a dielectric layer (e.g., SiN, SiO₂, AlN, AlₓO_{y}, AION, HFO₂, or other suitable dielectric material).

This sacrificial layer 402 can include a continuous or a discontinuous layer, such as can be formed using dry and/or wet chemical etching.

FIG. 4A shows an example in which a tri-layer structure can be formed. For example, the tri-layer structure can include an Alₓ₁Sc₁₋ₓ₁N layer 104, upon which the sacrificial layer 402 can be formed, upon which an Alₓ₂Sc₁₋ₓ₂N layer 404 can be formed, such as to help with lattice-matching with an overlaying GaN layer 406.

For example, the Alₓ₂Sc₁₋ₓ₂N layer 404 can include 1-x2 being between 0% and 20%, such as with the Alₓ₂Sc₁₋ₓ₂N layer 404 having a thickness between 1 nanometer and 5000 nanometers). The Alₓ₂Sc₁₋ₓ₂N layer 404 can act as a back barrier for a 2DEG electron gas 120 that can be formed in an overlaying GaN layer 406.

The tri-layer structure set of three layers 104, 402, 404 can be formed by low temperature (<400 degrees C) CVD, or PECVD PVD, such as before the HEMT GaN layer 406 is grown or regrown. The HEMT GaN layer 406 can be formed by higher temperature (e.g., 1000 degrees C) MOCVD, such as after cleaning the top Alₓ₂Sc₁₋ₓ₂N layer 404 of the tri-layer structure of three layers 104, 402, 404, such as with NH₃/H₂ at high temperature. This can help reduce or avoid any contamination issues at the regrowth interface of the GaN layer 406 (e.g., impurities incorporations, Si, O, Ga, etc.). Upon the HEMT GaN layer 406, an AlN layer 408 can be formed (e.g., having thickness of less than or equal to 2 nanometers) at high temperature (e.g., 1000 degrees C), such as by MOCVD. The GaN layer 406 can be grown to serve as the HEMT body region layer. In FIG. 4A, a p-type doped (e.g., p-GaN) layer 412 can optionally be provided, and selectively etched to leave behind p-GaN underlying gate regions 414, such as for corresponding enhancement mode HEMT devices, such as shown in FIGS. 4B and 4D. This can help make positive or increase the HEMT device threshold voltages, such as for a desired enhancement mode operation.

FIG. 4B shows a cross-sectional diagram of a resulting E-MODE HEMT.

FIG. 4C shows a cross-sectional diagram of a resulting D-MODE HEMT. FIG. 4D shows a cross-sectional diagram of a portion of a monolithic IC that can include both D-MODE HEMTs and E-MODE HEMTs.

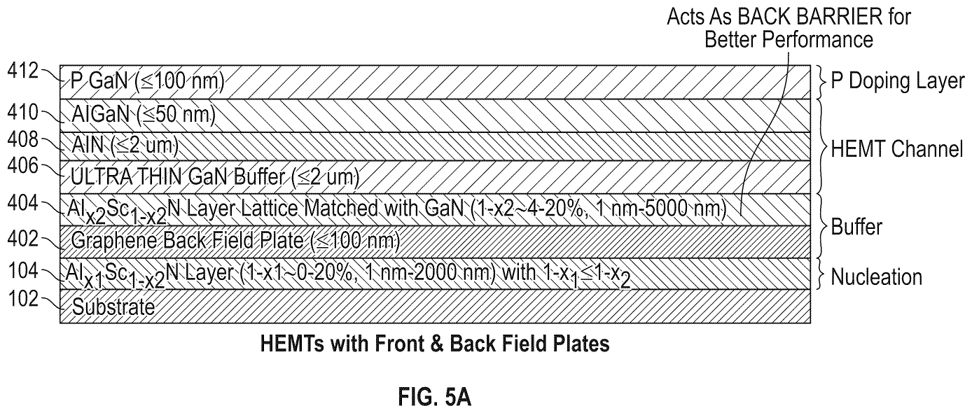

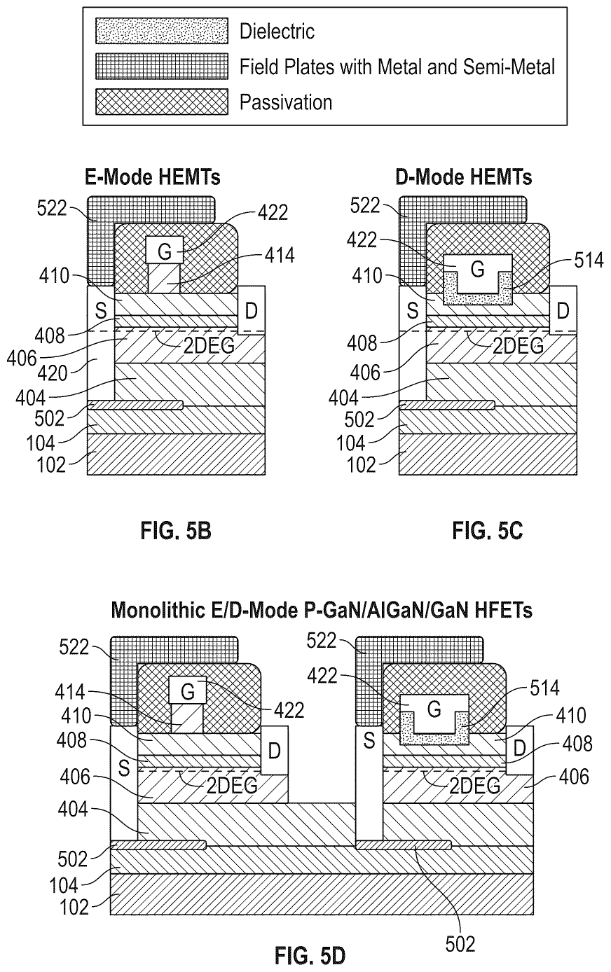

In FIG. 4A, the sacrificial (e.g., graphene or other material) layer 402 can optionally be removed, such as by chemical etching, mechanical exfoliation or other suitable technique. Alternatively, the sacrificial layer 402 need not be removed, such as shown in FIGS. 5A, 5B, 5C, and 5D. A graphene layer 402 will be electrically conductive. Therefore, a graphene layer 402 that has not been removed can optionally be used as a back side field plate 502, such as shown in FIGS. 5A, 5B, 5C, and 5D. Such a buried electric field plate 502 can be used to help provide electric field control. This can help reduce electric field around the gate region of the HEMT, which, in turn, can help provide better reliability. For example, if the electrically conductive source terminal 420 of an HEMT device physically contacts or is electrically interconnected to the electrically conductive graphene layer 404, such as shown in FIGS. 5B, 5C, and 5D, then the graphene layer 404 is at the same electrical voltage potential as the source terminal 420. Such a buried field plate 502 can be used alone or, optionally, in conjunction with an electric field plate located elsewhere, e.g., such as on the top surface of AlGaN/GaN layers, such as on the AlGaN layer 410.

In FIGS. 5A, 5B, and 5D, a p-type (e.g., p-GaN) layer can optionally be provided, and selectively etched to leave behind p-GaN gate-underlying regions 414, such as underlying gate terminals 422 for corresponding enhancement mode HEMT devices (such as shown in FIGS. 5B and 5D), such as to help make positive or increase their threshold voltages for a desired enhancement mode operation. For the depletion mode HEMTs on the same IC, a dielectric layer can optionally be provided, and selectively etched to leave behind dielectric gate-underlying regions 514, such as underlying gate terminals 422, such as for corresponding depletion mode HEMT devices, such as shown in FIGS. 5C and 5D.

FIG. 5B shows a cross-sectional diagram of a resulting E-MODE HEMT, such as which can include a back-side field plate 502. FIG. 5C shows a cross-sectional diagram of a resulting D-MODE HEMT, such as which can include a back-side field plate 502. FIG. 5D shows a cross-sectional diagram of a portion of a monolithic IC that can include both D-MODE HEMTs and E-MODE HEMTs, such as which can include a back-side field plate 502.

The back-side field plate 502 can be constructed such as by using (and not sacrificially removing) the graphene layer 402. Optionally, a top-side field plate 522 can also be provided, such as shown in FIGS. 5B, 5C, and 5D, such as for either or both of enhancement mode HEMTs and/or depletion mode HEMTs, such as which can be co-integrated on the same IC. As shown in FIGS. 5B, 5C, and 5D, the source region 420 can be formed to extend down to (or to otherwise electrically interconnect to) the back-side field plate 502 region, and can be interconnected with and electrically coupled to the optionally-included top-side field plate 522.

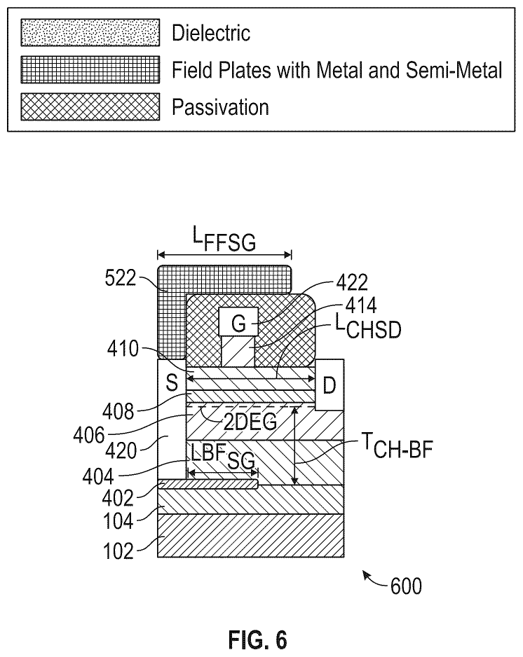

FIG. 6 illustrates a cross-sectional diagram of an illustrative example of an enhancement mode HEMT 600, along with an illustrative example of suitable dimensions of certain regions of the illustrated HEMT. In an illustrative example, a source-drain channel length LCHSD can be in a range of 0.200 microns to 100 microns; the channel width, WCHSD can be in a range of 2 microns to 100 microns; a back field plate length LBFSG can be in a range of 30 nanometers to LCHSD; a back side field plate width WBFSG can be in a range of 30 nanometers to WCHSD; a front field plate length LFFSG can be in a range of 30 nanometers to LCHSD, a front field plate width can be in a range of 30 nanometers to WCHSD, a distance TCH-BF of the channel to the back field plate can be in a range of 50 nanometers to 20 micrometers.

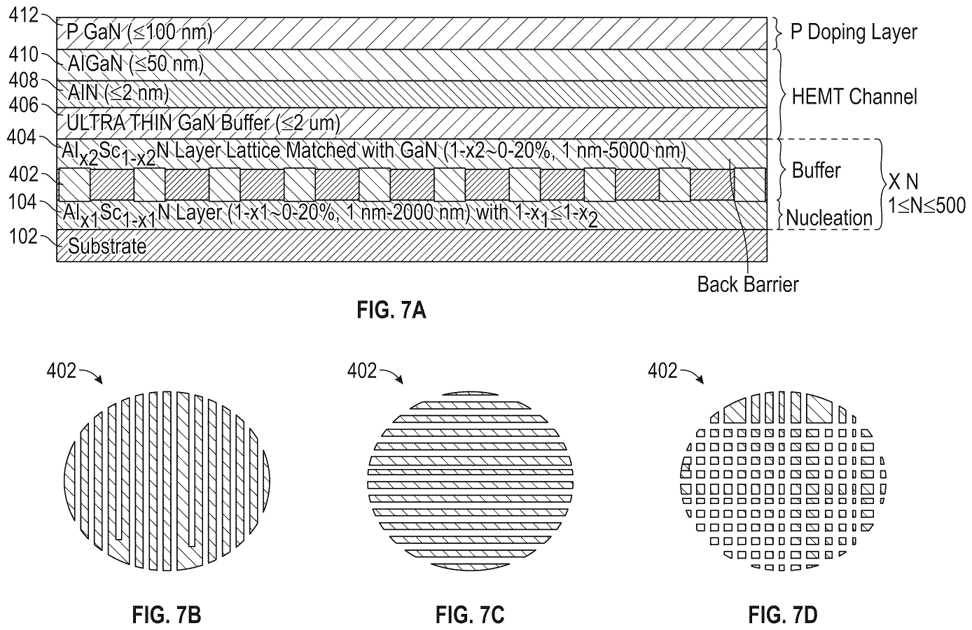

FIGS. 7A, 7B, 7C, and 7D illustrate an example in which the graphene or other sacrificial layer 402 can be selectively patterned, such as after forming the Alₓ₁Sc₁₋ₓ₁N nucleation layer 104 and before forming the Alₓ₂Sc₁₋ₓ₂N layer buffer layer 404 that can serve as the back barrier. In FIGS. 7B, 7C, and 7D various top views (looking down at the wafer) are provided, showing possible different orientations of the selectively patterned sacrificial layer 402, portions of which can be left behind, such as to form back-side field plates 502, such as in the top view illustration of FIG. 7D showing “islands” of graphene or other sacrificial layer 402 material that can be left behind, such as for forming distinct electrically conductive back-side field plates 502 or other desired structures. Pre-patterning the wafer, such as using wet or dry chemical etching before depositing the Alₓ₁Sc₁₋ₓ₁N nucleation layer 104 can lead to higher crystalline quality, such as by reducing bending dislocations.

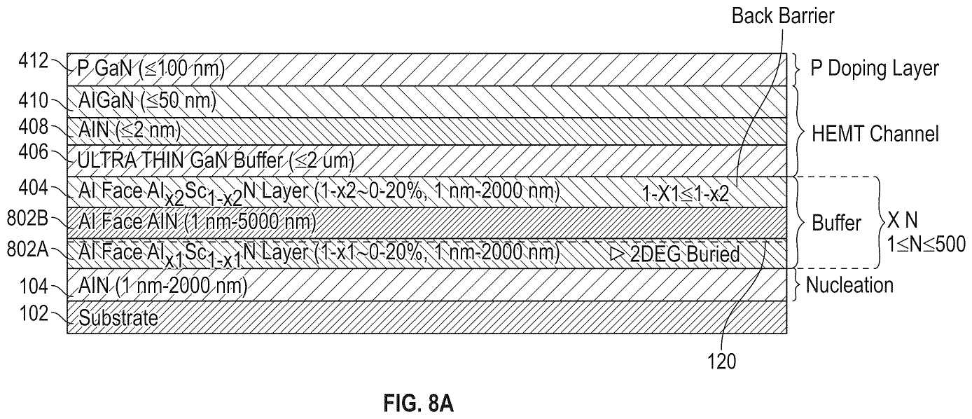

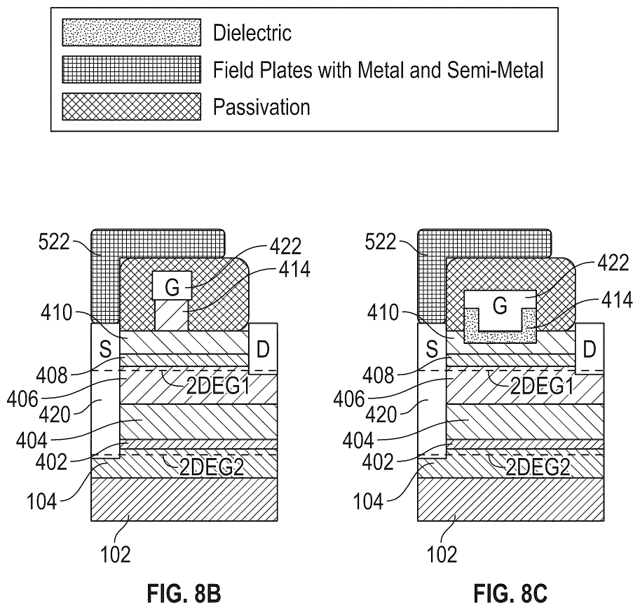

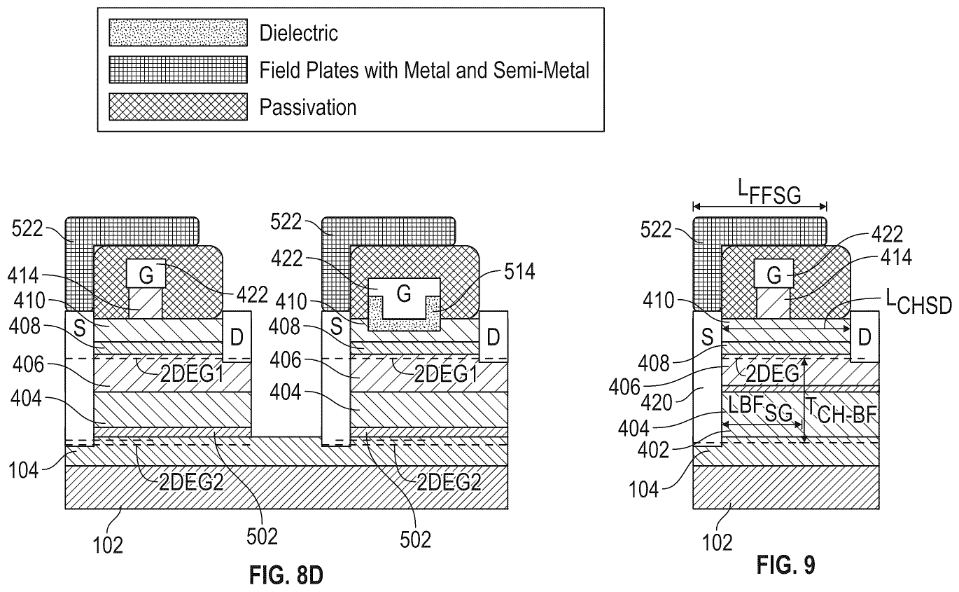

FIG. 8A illustrates an example in which the back-side field plate 502 need not be formed by leaving behind an island of graphene or other sacrificial layer 402 material, but instead can involve forming a AlN/Aₓ₁Sc₁₋ₓ₁N bi-layer 802A-B in which a 2DEG electron gas 120 can be created, such as to help serve as all or a portion of a back-side field plate 502. FIG. 8A illustrates an example in which an AlN nucleation layer 104 can be formed on the Si or other substrate 102. Upon the AlN nucleation layer 104, an Al-faced Aₓ₁Sc₁₋ₓ₁N layer 802A can be formed, with (1-x1) being less than 20 % and having a thickness between 1 nanometer and 2000 nanometer, in an illustrative example. A 2DEG electron gas 120 buried channel or buried field plate 502 can be created in this layer 802A, such as by forming thereupon an Al faced AlN layer 802B (e.g., 1 nanometer—5000 nanometer in thickness). Thereupon, an Al-faced Alₓ₂Sc₁₋ₓ₂N layer 404 can be formed, such as with (1-x2) being less than 20% and having a thickness between 1 nanometer and 2000 nanometer, and with x1 being less than or equal to x2. Thereupon an ultra-thin GaN buffer layer 406 (e.g., less than or equal to 2 microns thickness) can be formed, such as to serve as an HEMT body region layer. Thereupon, an AlN layer 408 can be formed, such as with a thickness of less than or equal to 2 nanometers.

Thereupon, an AlGaN layer 410 can be formed, such as with a thickness of less than or equal to 5 nanometers. Thereupon a p-type GaN layer 412 can be formed, such as with a thickness of less than or equal to 100 nanometers, such as which can be selectively removed to leave behind p-type GaN gate-underlying regions 414 such as for establishing or increasing the threshold voltage of enhancement mode HEMT devices such as for a low voltage or for a high voltage application, as desired.

Thus, in FIG. 8A, a lattice-matched AlScN back barrier buffer can be provided, together with a buried back-field plate 502 that can be provided using an electrically conductive 2DEG electron gas 120, which can help to improve reliability of a resulting HEMT.

FIGS. 8B, 8C, and 8D show illustrative examples of cross-sections of resulting depletion mode (FIG. 8C) and enhancement mode (FIG. 8B) HEMT structures, such as can be formed in accordance with the techniques explained with respect to FIG. 8A and elsewhere herein. As shown, the source regions 402 of the HEMTs can be made to contact the Alₓ₁Sc₁₋ₓ₁N layer 802A in which the buried electric field plate 502 can be formed by manufacturing the 2DEG region 120 therein. The 2DEG region 120 of the buried field plate 502 can be formed by selective patterning at manufacturing to extend all the way between the source region 402 and the drain region 114, if desired, or can be selectively patterned such that the 2DEG (e.g., 2DEG2) region 120 extends under the gate region 422, but need not extend all the way to the drain region 114, depending on the desired properties of the resulting HEMT appropriate to the particular use case.

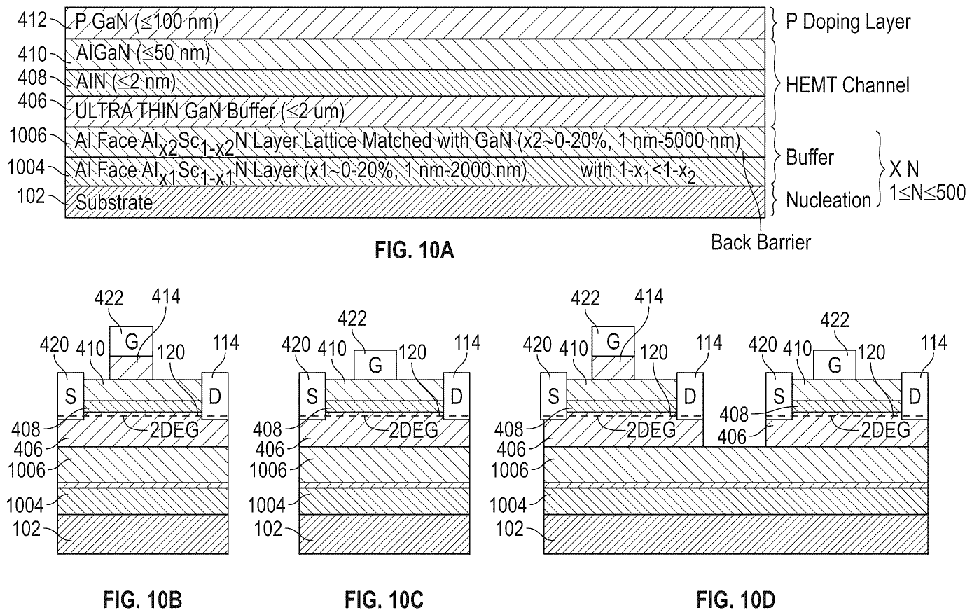

FIG. 9 illustrates a cross-sectional diagram of an illustrative example of a corresponding enhancement mode HEMT having a buried 2DEG 120 back-field plate 502. In an illustrative example, suitable dimensions of certain regions of the HEMT illustrated in FIG. 9 can follow those described above with respect to FIG. 6. FIGS. 10A, 10B, 10C, and 10D include cross-sectional diagrams of an illustrative example of an approach that can omit the AlN nucleation layer 104 upon the Si or other substrate 102. Instead, a “superlattice” can be employed, such as to help generate compressive stress for lattice-matching with an overlying GaN layer. The superlattice can be constructed by an Al-faced AlₓSc₁₋ₓN layer 1004 on the underlying Si or other substrate 102. In an example, (1−x1) can be less than 20%, and the thickness of the Al-faced A₁ₓSc₁₋ₓN layer 1004 can be between 1 nanometer and 2000 nanometers. Upon the Al-faced A₁ₓSc₁₋ₓN layer 1004, an Al-faced Alₓ₂Sc₁₋ₓ₂N layer 1006 can be formed. This combination of layers 1004 and 1006, with (1−x1) being less than or equal to (1−x2), can form a superlattice. The resulting superlattice can generate compressive stress comparable to that of an AlN/GaN stack, but the Alₓ₂Sc₁₋ₓ₂N layer 1006 can be lattice-matched to the overlying GaN layer 406, unlike AlN, which will create a lattice mismatch at its interface with an overlaying GaN layer. FIGS. 10B, 10C, and 10D show various examples of enhancement mode and depletion mode HEMTs, such as which can be monolithically co-integrated on the same IC, such as shown in FIG. 10D.

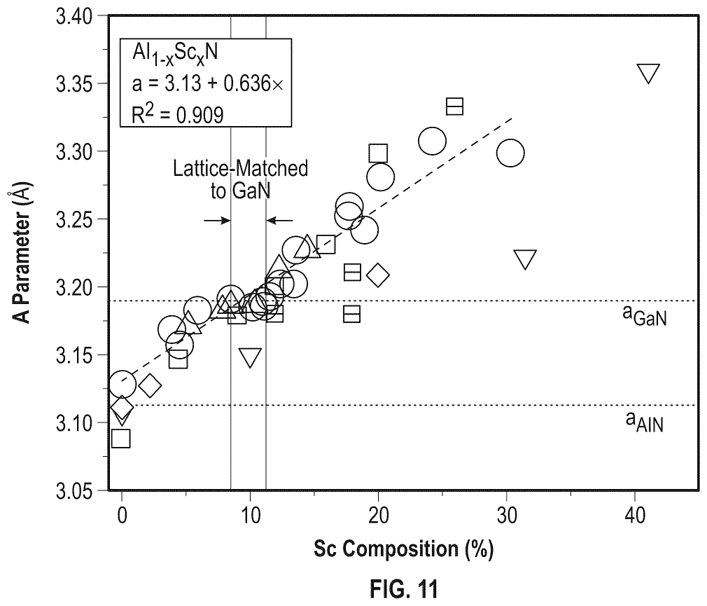

FIG. 11 shows a graph of lattice constant parameter, a, in Angstroms, VS.

percentage of Scandium (Sc) composition for various compositions of AlₓSC₁₋ₓN.

The lattice constant of GaN is a_{GaN}=3.189 angstroms, the lattice constant of AlN is a_{AlN}=3.112 angstroms, and the lattice constant of ScN is a_{ScN}=4.50 angstroms.

Using linear interpolation for the alloy AlₓSc₁₋ₓN, the lattice constant of the ally is a_{AlxSc1-xN}=X*a_{AlN}+(1−x) ascN. Setting the lattice match condition a_{AlxSc1-xN}=a_{GaN} and x*a_{AlN}+(1−x) a_{ScN}=a_{GaN}, and solving for x, yields x=a_{Gan}-a-_{ScN}/a_{AlN}-a_{ScN}, Or x=0.945. Thus, in theory the percentage composition of Sc is x˜5.5%, and empirically is between 8 percent and 12 %, or possibly even up to 20%. In sum, it is possible to lattice match AlₓSc₁₋ₓN to GaN fairly well, which is advantageous.

To recap, examples have been described herein explaining, among other things, that a buffer layer, such as of a lattice-matched Alₓ₁Sc₁₋ₓ₁N/Sacrificial layer/Alₓ₂Sc₁₋ₓ₂N, can be lattice-matched to an overlying region of GaN. This can help facilitate high crystal quality in the overlying region of GaN. The overlying region of GaN can be regrown by MOCVD. A sacrificial layer can be fully or partially conserved, such as to provide regions that can be used as a back-field plate 502. The back-field plate 502 can help locally reduce the electric field around the gate region of a high voltage of other HEMT device. This, in turn, can help augment the performance and reliability of such a HEMT device. The top Alₓ₂Sc₁₋ₓ₂N layer 404 can also act as a high bandgap energy back barrier, and can be formed thicker than certain other back barriers because the top Alₓ₂Sc₁₋ₓ₂N layer 404 can be lattice-matched to the overlying GaN layer 406. The resulting HEMT or other devices can be more efficient, because less defects will be generated and present due the lattice-matching between the Alₓ₂Sc₁₋ₓ₂N layer 404 and the overlying GaN layer 406. The present approaches to nucleation and buffer techniques can be used for many applications. Such applications can include 12V to 1700V applications, such as by modulating the thickness of nucleation layer 104 and the thickness of the lattice-matched Alₓ₂Sc₁₋ₓ₂N layer 404 in the stack of the Alₓ₁Sc₁₋ₓ₁N/Sacrificial layer/Alₓ₂Sc₁₋ₓ₂N layers. The resulting average breakdown voltage can be about two to five times higher than other approaches to nucleation layer and buffer layer techniques such as using high temperature (e.g., 1000 degrees Celsius) MOCVD.

Another problem faced by certain approaches to providing a nucleation layer and a buffer layer on a Si substrate for use in a GaN-based device. One approach can start with a Si substrate 102, with an AlN nucleation layer 104 formed thereupon. Upon the AlN nucleation layer, a graded stack of three layers of AlGaN can be successively formed thereupon with decreasing Al content in a direction away from the Si substrate 102. Upon the graded stack of three layers of AlGaN, a 2 to 3 micron thick GaN layer 108 can be formed. Upon this GaN layer 108, an AlGaN layer 110 can be formed thereupon for HEMT active device formation.

Alternatively, a thick superlattice buffer structure can be formed to replace the graded stack. This thick superlattice structure can include repeating thin layers of GaN and AlGaN. Both of these approaches (graded stack and superlattice) can have issues with traps being created in the thick graded or superlattice buffer layers needed for high voltage applications, such as which can exceed 650 Volts, for example. Both of these approaches can suffer from poor device yield, can add 50% to 85% to the epitaxy component of manufacturing costs, and can need longer pre-cleaning of the MOCVD reactor before GaN can be grown thereupon. This can mean lower wafer growth throughput and can impact wafer reproducibility and GaN HEMTs device yield.

It is recognized that, instead of providing a thick graded AlGaN stack or a GaN/AlGaN superlattice between the Si substrate and the GaN layer to be used as the HEMT body region in which active channels are formed, a low-cost buffer can be grown on the backside of the Si substrate 102, such as explained herein.

For example, using a thick graded AlGaN stack or a GaN/AlGaN superlattice can be avoided, such as by instead growing an AlₓSc₁₋ₓN layer on the backside of the Si substrate 102. This backside AlₓSc₁₋ₓN layer can be grown by using low temperature (e.g., <400 degrees Celsius) chemical vapor deposition (CVD) with concurrent physical vapor deposition (PVD) process, which can involve orienting the wafers being processed vertically within a chamber, such as to allow sputtering to occur. This CVD with concurrent PVD approach (e.g., instead of using a higher temperature MOCVD) can allow creation of a AlₓSc₁₋ₓN layer on the backside of the Si substrate 102, and can employ a CVD with concurrent PVD chamber, such as available from Element 3-5 GmbH (Baesweiler, Germany). Using a thin AlN nucleation layer 104 on the top side of the Si substrate 102, the Si substrate 102 wafer can be etched or partially etched from the backside of the Si substrate 102, such as to thin the Si substrate 102 wafer to a desired thickness. The AlN nucleation layer 104 on the top side of the Si substrate 102 wafer can be thickened with low cost and low temperature, such as using the backside AlScN layer formed using low temperature (<400 degrees C) CVD with concurrent PVD on the backside of the Si substrate 102 wafer, without generating as high thermal stress as would be generated the comparative approach using high temperature (e.g., 1000 degrees Celsius) MOCVD to grow a thick graded AlGaN stack or a GaN/AlGaN superlattice, both of which can be omitted using the present approach.

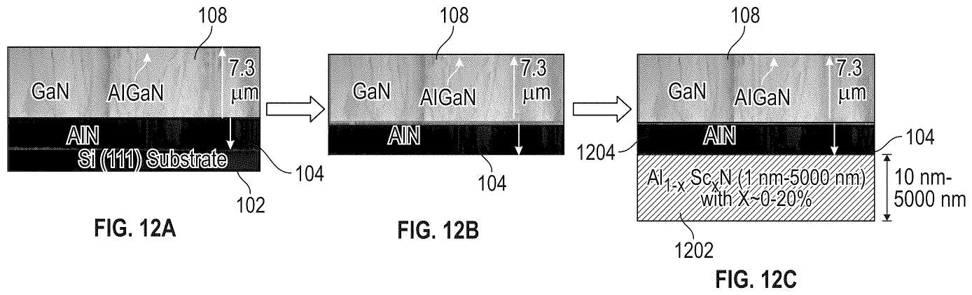

FIGS. 12A, 12B, and 12C illustrate an example of the present approach of employing low temperature CVD with concurrent PVD to form the AlxSc1-xN layer 1202 on the backside of the (e.g., thinned) Si substrate 102. This allows using a thin AlN buffer layer 1204, such as both for LV applications and also for HV applications that previously required a thick AlN buffer, such as explained above.

FIG. 12A shows an example in which the initial structure can include a Si substrate 102. Upon the Si substrate 102, a thin (e.g., less than 2 micron thickness) AlN layer 104 can be formed. The AlN layer 104 can serve as a nucleation or buffer layer. Upon the AlN layer 104, a GaN layer 108 can optionally be formed, such as using high temperature MOCVD.

FIG. 12B shows an example in which the Si substrate 102 can be partially or fully removed. Such partial or full removal of the Si substrate 102 can employ one or more of etching, chemical mechanical planarization, or the like.

FIG. 12C shows an example in which a 10 nanometer to 5000 nanometer Alₓ Sc₁₋ₓN layer 1202 can be formed on the backside of the Si substrate 102, to the extent that it has not been completely removed. Otherwise the Alₓ Sc₁₋ₓN layer 1202 can be formed upon the backside of the overlaying AlN layer 104. In either case, forming the Alₓ Sc₁₋ₓN layer 1202 can employ using, e.g., at low temperatures of less than 400 degrees Celsius, deposition using a CVD with concurrent PVD chamber such as available from Element 3-5 GmbH (Baesweiler, Germany). Similarly, for a higher-voltage application, the Alₓ Sc₁₋ₓN layer 1202 can be similarly formed to a larger thickness, such as which can be even greater than 2 microns in thickness.

Another technical challenge is that GaN grown on a Si substrate can have more than 109 dislocations per cm² due to the large tensile stress produced. Also, the resulting structure can have a large thermal resistance, because of the silicon wafer substrate being used. During operation of a resulting HEMT device fabricated in this manner, heat can be trapped at the buffer and at the AlN/Si and thick Si wafers and at the material interfaces.

By contrast, GaN grown on a silicon carbide (SiC) or a sapphire substrate will have less than 10⁹ dislocations per cm² because of the lesser tensile stresses involved as compared to growing GaN on a Si wafer substrate. Therefore, using GaN grown on a SiC or sapphire substrate needs less thick of a buffer layer between the underlying substrate and the overlying GaN layer. This thinner buffer layer, in turn, presents less thermal resistance and, therefore, improved device operation. However, SiC material is very expensive, and can be approximately between 300 microns and 600 microns thick, when the SiC is used as a substrate to support the GaN grown thereupon.

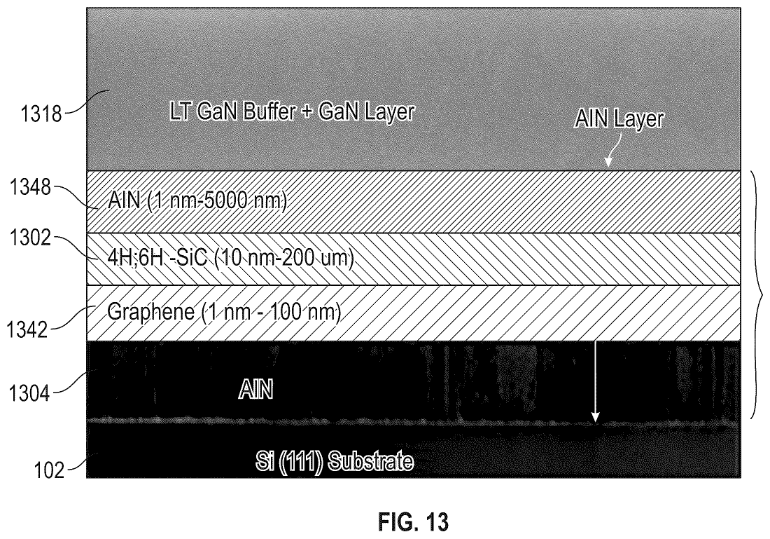

FIG. 13 shows an example of an approach that can provide a low cost SiC buffer for high crystalline quality GaN grown thereupon. Such an approach can help permit thermal management, such as by providing high thermal conductivity, such as to help carry away heat during device operation.

In FIG. 13, instead of using a thick SiC wafer substrate, a 4H;6H SiC buffer layer 1306 (e.g., 10 nanometers to 200 microns in thickness) can be grown upon a graphene layer 1342 (e.g., 1 nanometer to 100 nanometers in thickness). The graphene layer 1342 can be formed upon an AlN nucleation layer 1304, the AlN nucleation layer formed upon a Si substrate 102. An AlN layer 1348 (e.g., 1 nanometer to 5000 nanometers in thickness) can be grown upon the 4H;6H SiC buffer layer 1302. On the AlN layer 1348, a low temperature GaN buffer layer upon which a thicker GaN layer 1318 can be formed. The set of layers 1320 (e.g., AlN layer 1348, graphene layer 1342, 4H;6H SiC layer 1302, AlN layer 1348), can all be formed using low temperature CVD with concurrent PVD, such as described herein. The low temperature GaN buffer layer portion of the GaN layer 1318 can also be formed using low temperature CVD with concurrent PVD, such as described herein. The remaining portion of the GaN layer 1318, which can serve as the body region for a HEMT device channel, can be formed using either low temperature CVD with concurrent PVD, as described herein, or by using high temperature (e.g., 1000 degrees C) MOCVD.

The approach shown in FIG. 13, with the SiC buffer layer 1302, can be cheaper than the using a thicker SiC wafer as a substrate instead of a Si substrate 102. There can be less dislocations using the SiC buffer layer 1302 approach shown in FIG. 13, as well as better thermal conductivity, less vertical thermal resistance.

Moreover, the Si substrate 102 can be manufactured in and sourced from a CMOS foundry, unlike using a thicker SiC wafer as a substrate instead of the Si substrate 102.

Another technical challenge that presents an opportunity for technical improvement is that GaN grown on Si has a lower thermal conductivity than GaN grown on diamond. But GaN growth on diamond can be difficult, because of lattice mismatch therebetween, and because the diamond wafer is difficult to scale up to wafer diameters of 6 inches, 8 inches, or 12 inches, for example. The present disclosure recognizes, among other things, that it would be beneficial to get the thermal conductivity associated with diamond, while also getting high GaN crystal quality. One solution is to post-process the backside of a Si substrate and then deposit AlN and diamond layers, such as described herein.

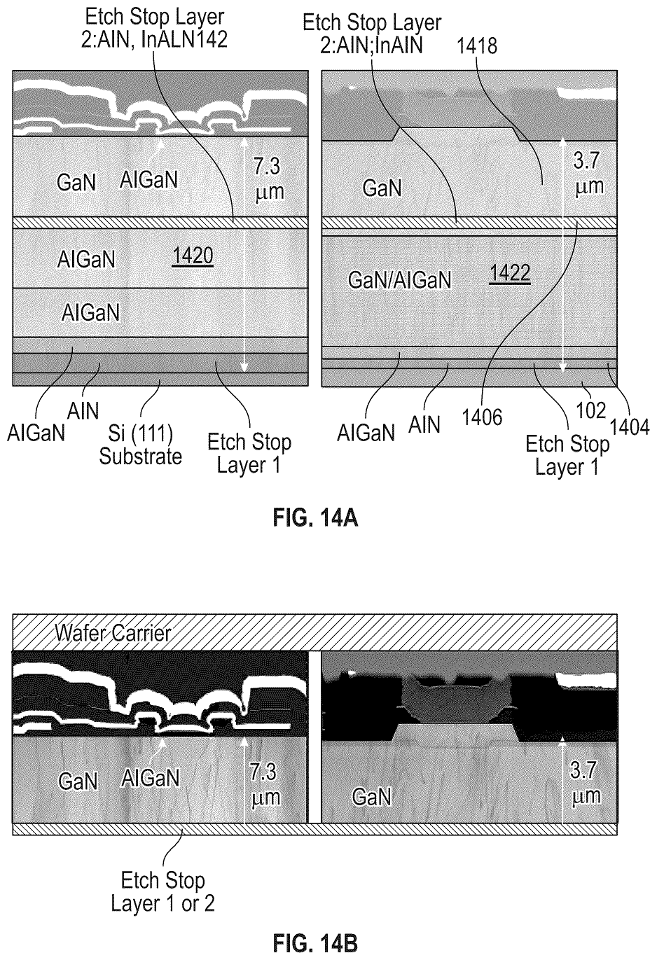

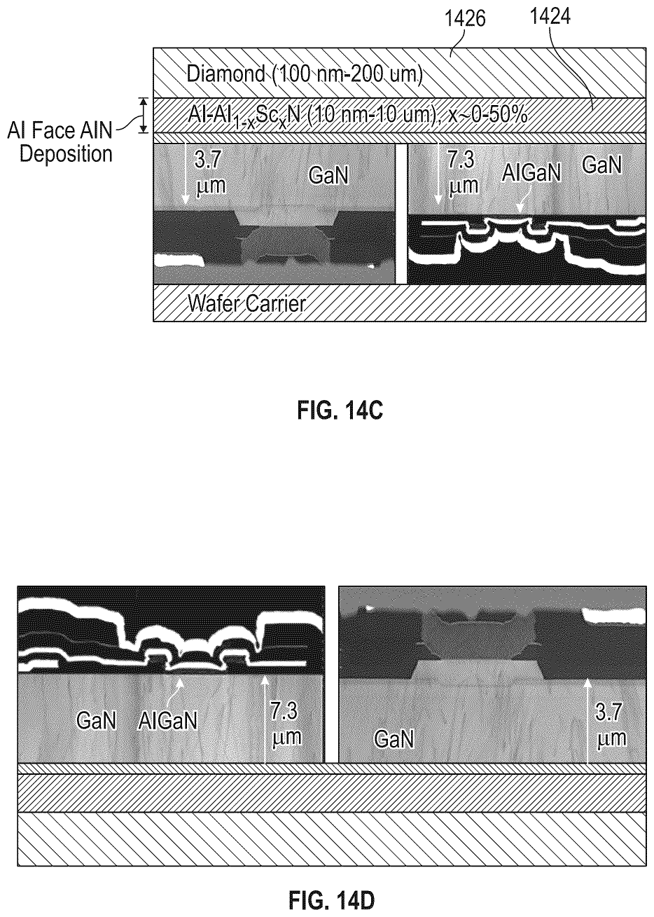

FIGS. 14A, 14B, 14C, and 14D show an example in which a high crystalline Al-AlScN/diamond buffer can be provided, such as for manufacturing AlGaN/GaN HEMTs. The AlScN can be lattice-matched with single crystalline or polycrystalline diamond.

FIG. 14A shows an example of how a first etch stop layer 1402 can be provided using the AlN nucleation layer 1404 on the Si substrate 102. A second etch stop layer 1406 can be provided at the underside of the GaN HEMT body region layer 1418, such as by providing a layer of AlN or InAlN as the second etch stop layer 1406. The underlying Si substrate 106 and either the graded stack of AlGaN layers 1420 or the superlattice stack 1422 of thin GaN/AlGaN layers (described elsewhere herein) can be etched away, such as using etching that is stopped by the second etch stop layer 1406, leaving the overlying areas that can be used to form active devices using the GaN body region 1418, such as shown in FIG. 14B.

Then, as shown in FIG. 14C, low temperature CVD with concurrent PVD can be used to grow a backside lattice-matching layer 1424, such as of Al-AlₓSc₁₋ₓN (e.g., 10 nm-10 um thickness), (1-x)˜0-20%. Upon the Al-AlₓSc₁₋ₓN backside lattice-matching layer 1424, a polycrystalline or monocrystalline diamond layer 1426 can be grown thereupon from the backside. This approach can help provide better thermal characteristics and improved vertical breakdown voltage ratings for the resulting HEMT devices formed using the GaN body region 1418.

FIG. 14D illustrates how the structure shown in FIG. 14C can be flipped over after forming the diamond layer 1426, such as for further manufacturing via semiconductor processing. The single-crystal or polycrystalline diamond layer 1426 can be formed on the backside of the GaN HEMT body region layer 1418, in which the 2DEG channel is to be formed. The AlScN layer 1424 can be formed to a thickness that can provide a desired modulation of the vertical breakdown voltage of the HEMT devices, and can act as an energy “back barrier” such as described elsewhere herein.

Another technical challenge is that GaN grown at high temperature (e.g., 1000 degrees C) on Si can have too much thermal stress present during cooling down to room temperature. This stress during cooling can lead to defects, such as cracks in the GaN. A compliant buffer layer can be used to try to help reduce stress, but that may not be enough for thick GaN layers and complex device structures that must be accommodated by the processing during semiconductor device manufacturing.

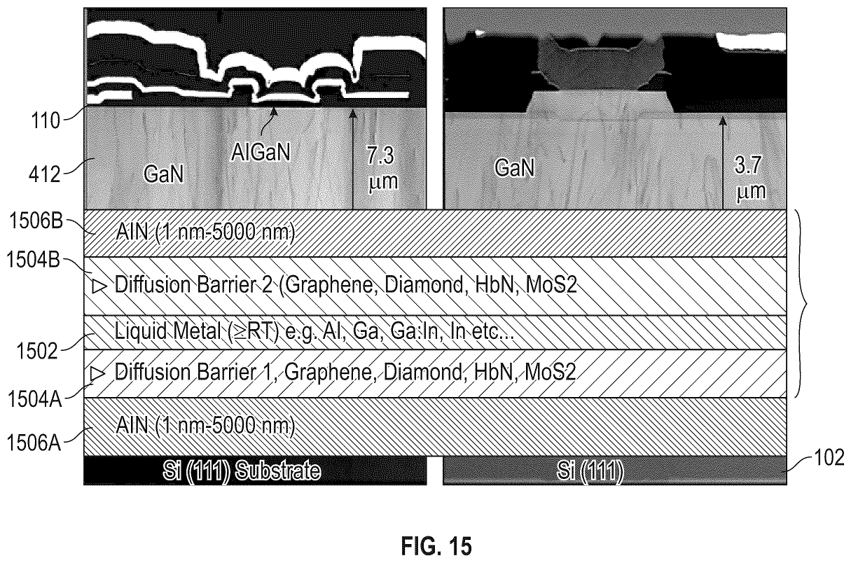

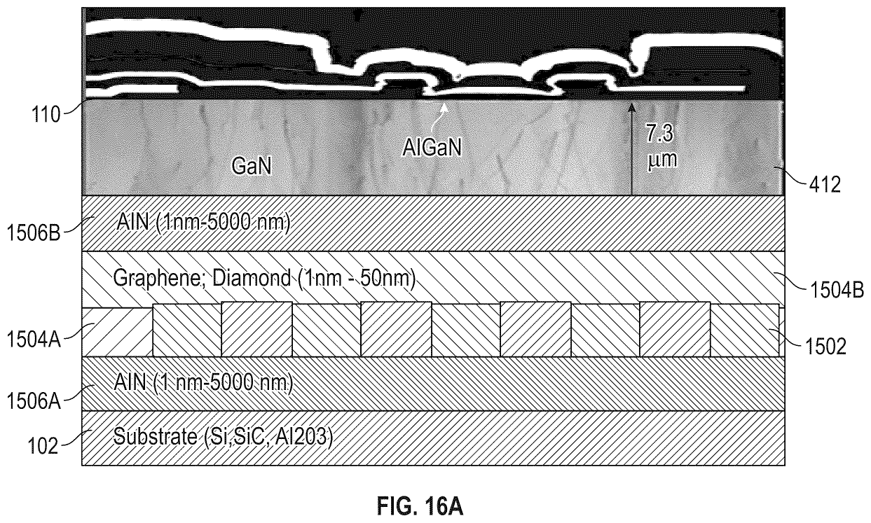

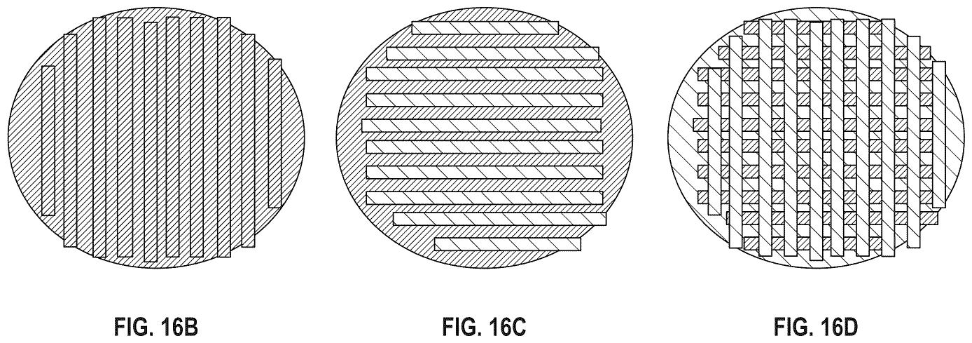

The compliant buffer layer can be selected such that it phase-changes, such as from a solid-state at room temperature to a liquid state under the epitaxial growth conditions being employed. For example, as shown in FIG. 15, an Al, Ga, Ga: In, In, or other like film can be used as a phase-changing compliant layer 1502. In the Al film example, the film can have a melting temperature of around 660 degrees Celsius and a boiling point temperature of about 2470 degrees Celsius at a chamber pressure of 760 Torr. Diffusion barrier layers 1504A-B can be located on opposing sides of the compliant layer 1502 sandwiched therebetween, such as to inhibit diffusion from the compliant layer 1502, such as while the compliant layer 1502 is at a temperature such that it is not in a solid-state. The diffusion barrier layers 1504A-B, together with the phase-changing compliant layer 1502, can collectively be sandwiched between AlN layers 1506A-B. The set of layers 1502, 1504A-B, 1506A-B can substitute for (and be thinner than) the AlN nucleation layer and either the graded stack of AlGaN layers 1420 or the superlattice stack 1422 that were described previously. This can allow growth of a thick overlying GaN region, such as which can be greater than or equal to 5 microns in thickness.

In FIG. 15, a Si, SiC, or Al₂O₃ substrate 102 can be used as a starting material. Upon the Si, SiC, or Al₂O₃ substrate 102, an AlN layer 1506A can be formed (e.g., 1 nm to 5000 nm thick), such as can provide a nucleation layer. Upon the AlN layer 1506A, a graphene or diamond or other diffusion barrier layer 1506A can be formed (e.g., 1 nm to 50 nm thick). Upon the graphene or diamond or other (e.g., HbN, MOS2, etc.) diffusion barrier layer 1506A, the phase-changing compliant layer 1502 can be formed. For example, the phase-changing compliant layer 1502 can include a solid-state Al layer 1502 can be formed (e.g., 1 nm to 200 nm thick). Upon the phase-changing compliant layer 1502, another graphene or diamond or other diffusion barrier layer 1504B can be formed (e.g., 1 nm to 50 nm thick). Upon the diffusion barrier layer 1504B, an AlN layer 1506B can be formed (e.g., 1 nm to 5000 nm thick). Upon the AlN layer 1506B, a GaN layer 412 can be grown (e.g., using high temperature MOCVD epitaxy). The GaN layer 412 can serve as a HEMT body region in which a 2DEG is created. Upon the GaN layer 412, a barrier layer such as an AlGaN layer 110 can be formed. During the MOCVD epitaxy, conditions can include a temperature between 660 degrees Celsius and 1100 degrees Celsius at a MOCVD chamber pressure of between 50 Torr and 250 Torr. Under these MOCVD conditions, the Al or other phase-changing compliant layer 1502 layer is changed from its room temperature solid-state to a liquid-state. Thus, under MOCVD conditions, the phase-changing compliant layer 1502 can provide a liquid state compliant buffer during the MOCVD growth of the GaN layer 412. This can help reduce heating and cooling stress and resulting dislocations or other defects in the GaN layer 412, leading to better GaN HEMT or other semiconductor device performance.

FIGS. 16A, 16B, 16C, and 16D illustrate an example of how the techniques described herein, such as with respect to FIG. 15, including its phase-change-to-liquid compliant layer 1502 (e.g., which can be Al, Ga, Ga: In, In, or the like) can be further processed, such as to leave behind selectively patterned graphene, diamond, or other structures, along with selectively patterned aluminum regions 1602, such as which can be employed to provide back-side field plates 502, such as described elsewhere herein.

Although the present document has described various ways of employing low temperature CVD with concurrent PVD to form an alloy layer including an aluminum scandium nitride (AlₓSc₁₋ₓN) alloy layer, other alloy materials may also be suitable, such as can include using an aluminum indium nitride (AlₓIn₁₋ₓN) alloy layer instead of or in addition to the aluminum scandium nitride (AlₓSc₁₋ₓN) alloy layer

The above description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A method of making a compound semiconductor high electron mobility transistor (HEMT), including a body region and further including a source region, a drain region, and a gate region that define a gate-source access region and a gate-drain access region, the method comprising:
forming a first alloy layer over a substrate, the first alloy layer including an aluminum scandium nitride (Alₓ₁Sc₁₋ₓ₁N) alloy layer;
forming an intermediate layer over the first alloy layer;
forming a second alloy layer over the intermediate layer, the second alloy layer including an aluminum scandium nitride (Alₓ₂Sc₁₋ₓ₂N) alloy layer, wherein (1-x1) is less than or equal to (1-x2); and
forming a GaN layer over and substantially lattice-matched to the second alloy layer.

2. The method of claim 1, further comprising:
forming an AlGaN layer over the GaN layer; and
providing the body region of the HEMT in the GaN layer.

3. The method of claim 2, wherein the second alloy layer is formed to act as a back barrier for a 2DEG electron gas formed in the GaN layer by the AlGaN layer and the GaN layer.

4. The method of claim 1, in which the intermediate layer acts as a sacrificial layer, wherein at least a portion of the sacrificial layer is removed.

5. The method of claim 1, in which at least a portion of the intermediate layer is formed into an electrically conductive back field plate region.

6. The method of claim 1, wherein the intermediate layer comprises a two-dimensional material including at least one of graphene, MoS2, HbN, or silicon.

7. The method of claim 1, comprising forming the source region to electrically contact at least a portion of the intermediate layer to form a back field plate connection.

8. An integrated circuit device formed using the method of claim 1.

9. A method of making a compound semiconductor high electron mobility transistor (HEMT), including a body region and further including a source region, a drain region, and a gate region that define a gate-source access region and a gate-drain access region, the method comprising:
forming an AlScN superlattice, comprising:
forming a first alloy layer over a substrate, the first alloy layer including an aluminum scandium nitride (Alₓ₁Sc₁₋ₓ₁N) alloy layer; and
forming a second alloy layer over the first alloy layer, the second alloy layer including an aluminum scandium nitride (Alₓ₂Sc₁₋ₓ₂N) alloy layer, wherein (1-x1) is less than (1-x2);
forming a GaN layer over and substantially lattice-matched to the second alloy layer.

10. The method of claim 9, further comprising:
forming an AlGaN layer over the GaN layer; and
providing the body region of the HEMT in the GaN layer.

11. An integrated circuit device formed using the method of claim 9.

12. A method of making a compound semiconductor high electron mobility transistor (HEMT), including a body region and further including a source region, a drain region, and a gate region that define a gate-source access region and a gate-drain access region, the method comprising:
forming an AlN layer over a substrate;
forming a GaN layer over the AlN layer for providing a body region of the HEMT;
at least partially etching the substrate from a backside of the substrate; and
at the at least partially etched substrate backside, forming a backside Alₓ₁Sc₁₋ₓ₁N layer using low temperature chemical vapor deposition (CVD) with concurrent physical vapor deposition (PVD) at a temperature of less than or equal to 400 degrees Celsius.

13. The method of claim 12, further comprising forming a polycrystalline or monocrystalline diamond layer on the backside Alₓ₁Sc₁₋ₓ₁N layer.

14. An integrated circuit device formed using the method of claim 12.

15. A method of making a compound semiconductor high electron mobility transistor (HEMT), including a body region and further including a source region, a drain region, and a gate region that define a gate-source access region and a gate-drain access region, the method comprising:
forming an AlN layer over a substrate;
forming a graphene layer over the AlN layer;
forming a 4H;6H silicon carbide layer over the graphene layer;
forming an AlN layer on the silicon carbide layer; and
forming a GaN layer on the AlN layer.

16. The method of claim 15, wherein at least a portion of the GaN region is configured to provide a body region of the HEMT.

17. An integrated circuit device formed using the method of claim 15.

18. A method of making a compound semiconductor high electron mobility transistor (HEMT), including a body region and further including a source region, a drain region, and a gate region that define a gate-source access region and a gate-drain access region, the method comprising:
forming a first aluminum nitride layer over a substrate;
forming a first barrier layer over the aluminum nitride layer;
forming a solid-state phase-change compliant layer over the first barrier layer;
forming a second barrier layer over the phase-change compliant layer;
forming a second aluminum nitride layer over the second barrier layer; and
forming a GaN layer over the second aluminum nitride layer.

19. The method of claim 18, wherein forming the GaN layer includes using chemical vapor deposition at a temperature and a pressure that causes the phase-change compliant layer to change from solid-state to liquid state to provide compliance.

20. The method of claim 18, wherein forming the GaN layer includes providing the body region of the HEMT in the GaN layer.

21. An integrated circuit device formed using the method of claim 18
